(19) United States
(12) Patent Application Publication
(10) Pub. No.: US 2007/0066081 A1
(43) Pub. Date: Mar. 22, 2007

(54) Catalytic activation technique for electroless metallization of interconnects

(76) Inventors: Chin-Chang Cheng, Portland, OR (US); Yang Cao, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/233,298

(22) Filed: Sep. 21, 2005

(51) Int. Cl. H01L 21/31; H01L 21/469

(52) U.S. Cl. 438/758

(57) ABSTRACT

A method of forming a metal interconnect for an integrated circuit comprises providing a substrate that includes a trench formed in a dielectric layer, employing a first dry thermal process to deposit a barrier layer onto the dielectric layer and within the trench, employing a second dry thermal process to deposit a catalytic activation film on the barrier layer, employing a wet chemistry plating process to deposit at least one metal layer on the catalytic activation film to fill the trench, and planarizing the deposited metal layer to form an interconnect. The first and second dry thermal processes may be vapor deposition processes performed in sequence within a reaction chamber under vacuum, where the vacuum is not broken between processes. The wet chemistry plating process may be an electroless plating process or a combination of an electroless plating process and an electroplating process.

### BACKGROUND

In the manufacture of integrated circuits, metal interconnects are used to couple transistors together. Generally, an interconnect is formed by first etching a trench into a dielectric layer on a semiconductor wafer. A barrier layer and a metal seed layer are then deposited into the trench using physical vapor deposition (PVD) processes. This is generally followed by an electroplating process to fill the trench with metal. Finally, a chemical mechanical polishing (CMP) process may be used to remove excess material and complete the formation of the interconnect.

As integrated circuit dimensions continue to scale down, smaller and smaller interconnects become necessary, thereby requiring narrower trenches to be etched into the dielectric layers. Unfortunately, narrow trenches have aggressive aspect ratios that are difficult to fill with metal. One problem is that conventional metal seed layers tend to be relatively thick and often overhang at the top of the trenches, pinching off the trench opening and making it difficult or impossible for the subsequent electroplating process to completely fill the trenches with metal. This leads to the formation of voids within the trenches that increase resistance and decrease reliability. Unfortunately, thinner metal seed layers cannot be deposited using PVD without introducing discontinuities that lead to serious reliability issues.

Electroless plating is one alternative metal deposition process to form metal seed layers, thin barrier layers, and/or to directly fill the trenches with metal. Electroless plating is a process for depositing a metal onto a surface by chemical reduction in the absence of an external electric current. Electroless plating is a selective deposition and occurs at locations on the surface that may have a nucleation potential for the plating solution. One process for electroless plating of a metal utilizes a metal ion, a pH-adjusting agent, pH buffers, a complexing agent to maintain the metal in solution, at least one reducing agent, and optionally a wetting agent. Electroless plating has a conformal growth mechanism that produces uniform coverage.

Electroless plating has its own challenges that need to be overcome. One challenge is initiating electroless plating of metal on a non-catalytic substrate, such as a dielectric layer. Another challenge is creating good adhesion between an electrolessly plated metal and an underlying barrier layer, as most barrier layers are very chemically active and can instantaneously form a native oxide layer when exposed to air or an aqueous solution.

To initiate electroless plating on non-catalytic substrates, current technology utilizes different processes to deposit a metallic catalyst seed layer, such as palladium, onto the non-catalytic substrate. One process is a wet process that relies on coupling agents, such as azo-silane molecules, to bond the palladium to the non-catalytic substrate. This is known as a palladium immobilization process. Another process is a displacement process, however, this process only works when the under layer metallic element is less noble than the palladium and whose oxidation product is also soluble in an aqueous solution. Yet another process uses Sn(II) sensitizer to reduce ionic Pd(II) into metallic Pd(O), which are discrete particles/islands.

Unfortunately, the current technology processes mentioned above are tedious, difficult to control, and are limited by the properties of the underlying substrate. For instance, the wet process requires that the deposited palladium layer have no discontinuities in order for the subsequently deposited barrier and/or seed layer to also have no discontinuities. With the stringent requirements necessary in thin film deposition processes, the application of conventional electroless plating processes is very difficult. Accordingly, improved electroless plating processes are needed.

### BRIEF DESCRIPTION OF THE DRAWINGS

FIG. 1 illustrates a catalytic activation film in accordance with an implementation of the invention.

FIG. 2 illustrates a catalytic activation film and a metal seed layer in accordance with an implementation of the invention.

FIG. 3 illustrates a catalytic activation film and a metal-filled feature in accordance with an implementation of the invention.

FIG. 4 illustrates a catalytic activation film within a trench with an aggressive aspect ratio in accordance with an implementation of the invention.

FIG. 5 is a method for forming an interconnect using a catalytic activation film in accordance with an implementation of the invention.

FIG. 6 is a method for forming a barrier layer using a catalytic activation film in accordance with an implementation of the invention.

### DETAILED DESCRIPTION

Described herein are methods of using a catalytic activation film to enable an electroless deposition of metal to form semiconductor interconnects. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

In accordance with implementations of the invention, an electroless plating process may be initiated on surfaces, such as non-catalytic surfaces or other surfaces, using a dry thermal process and a thin catalytic activation film of a precious metal. The catalytic activation film provides the surface necessary for an electroless plating process to occur. For instance, some implementations of the invention use the catalytic activation film to initiate an electroless plating process on a barrier layer within a trench to form a metal seed layer or to fill the trench with metal. The catalytic activation film provides improved adhesion between the barrier layer and the eletrolessly plated metal. Other implementations of the invention use the catalytic activation film to initiate an electroless plating process directly on a dielectric layer to form a metal barrier layer. Here the catalytic activation film allows metal to be electrolessly plated on the non-catalytic dielectric surface.

The catalytic activation film may be directly deposited onto the surface using dry thermal processes such as physical vapor deposition (PVD), chemical vapor deposition (CVD), plasma enhanced chemical vapor deposition (PECVD), atomic layer deposition (ALD), ion-assisted atomic layer deposition (iALD), and ion cluster beam deposition (ICB). The coverage of the catalytic activation film does not have to be uniform or continuous, thereby allowing a very thin catalytic activation film to be deposited.

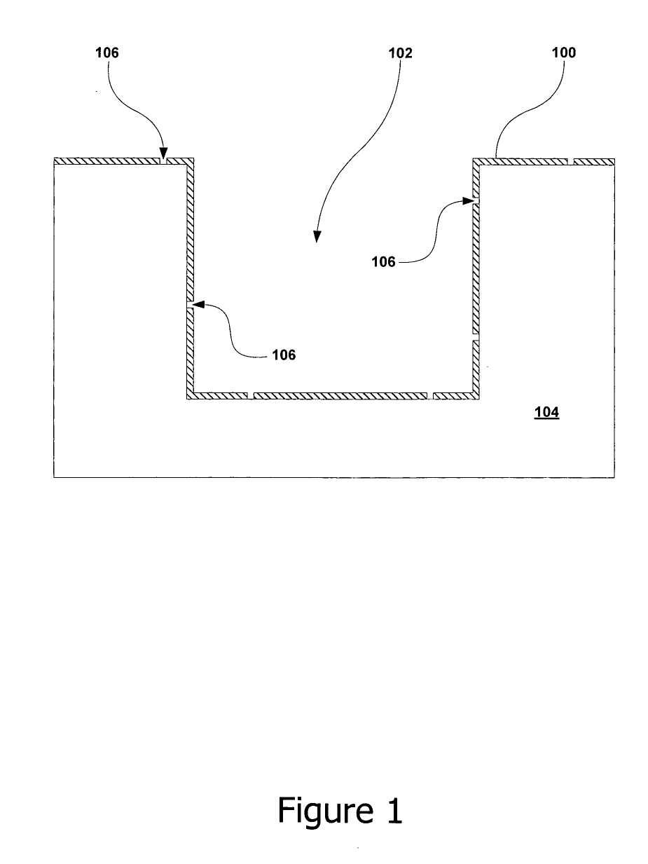

FIG. 1 illustrates an implementation of a catalytic activation film 100 that lines a trench 102 within a dielectric layer 104. In implementations, the catalytic activation film 100 may be formed from a thin film of a precious noble metal. In some implementations the catalytic activation film may be a continuous film having no discontinuities; in other implementations the catalytic activation film may be a film that includes one or several discontinuities 106, as shown in FIG. 1. As will be appreciated by those of ordinary skill in the art, allowing the catalytic activation film 100 to include one or more discontinuities 106 enables the deposition of a very thin catalytic activation film 100 relative to conventional seed layers. This is because unlike conventional seed layers, the thickness of the catalytic activation film 100 does not need to be built up until all of the discontinuities are filled. In implementations of the invention, the thickness of the catalytic activation film 100 may range from a partial monolayer to ten monolayers.

In accordance with implementations of the invention, the presence of discontinuities 106 in the catalytic activation film 100 does not adversely affect its ability to catalyze the electroless deposition of a metal layer onto a substrate. In other words, if the catalytic activation film 100 includes one or more discontinuities 106 (referred to herein as a “discontinuous catalytic activation film”), the film 100 will nevertheless enable the electroless deposition of a continuous metal layer having substantially no discontinuities onto a non-catalytic substrate or any other substrate.

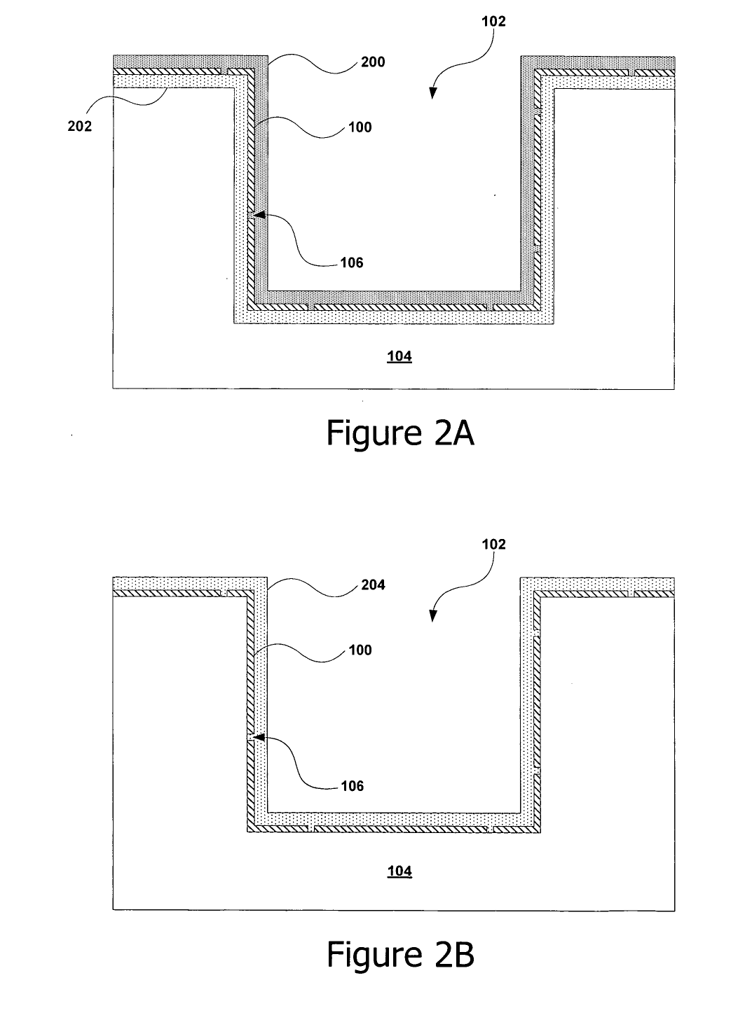

For instance, as shown in FIG. 2A, the discontinuous catalytic activation film 100 may enable the electroless deposition of a continuous metal seed layer 200 atop a previously deposited barrier layer 202 within an integrated circuit feature such as the trench 102. Even though the catalytic activation film 100 includes a number of discontinuities 106, the metal seed layer 200 is a continuous layer having no discontinuities. Similarly, as shown in FIG. 2B, the discontinuous catalytic activation film 100 may enable the electroless deposition of a continuous metal barrier layer 204 directly on the dielectric layer 104 within the trench 102. Even though the catalytic activation film 100 includes a number of discontinuities 106, the metal barrier layer 204 is a continuous layer having no discontinuities.

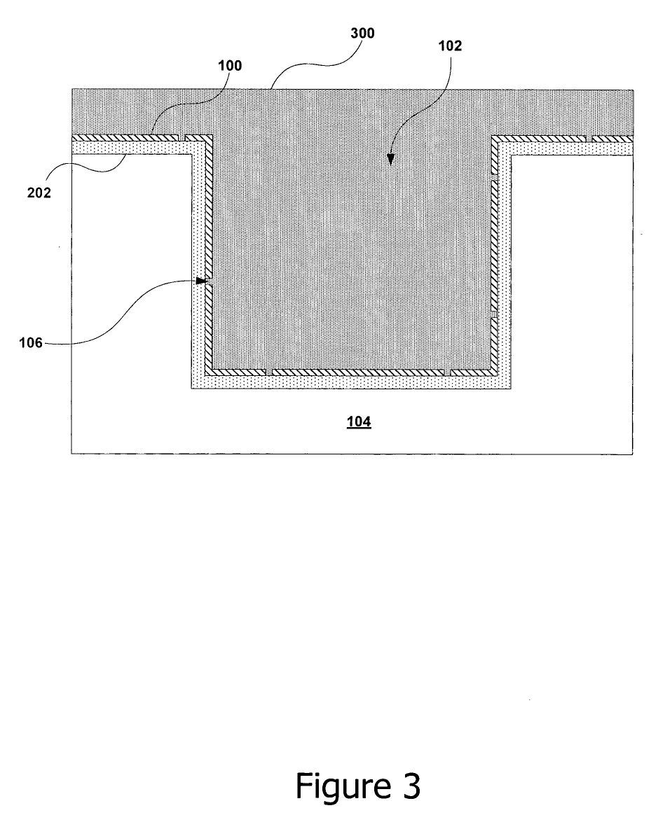

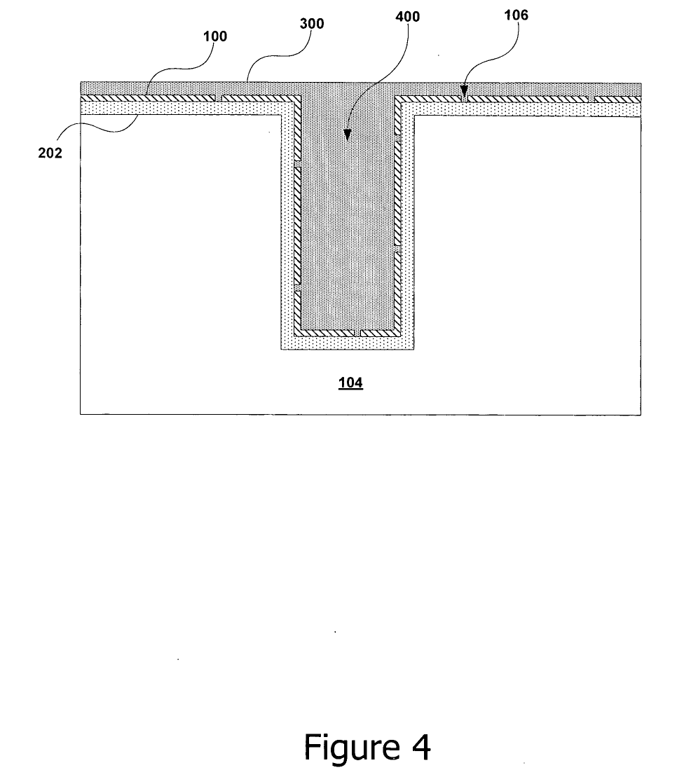

Alternatively, as shown in FIG. 3, the discontinuous catalytic activation film 100 may enable an electroless deposition process to completely fill the trench 102 with a metal 300. Again, the presence of discontinuities 106 in the catalytic activation film 100 does not affect the quality of the metallization. And as shown in FIG. 4, if the feature has an aggressive aspect ratio, such as a narrow trench 400, the thinness of the discontinuous catalytic activation film 100 enables the trench 400 to be filled with the metal 300 without issues such as overhang at the trench opening that leads to void formation. And because electroless deposition processes tend to have better success at plating metal into features with aggressive aspect ratios, the combination of the catalytic activation film 100 of the invention and an electroless plating process can enable high quality, void-free filling of aggressive aspect ratio features.

As stated above, the catalytic activation film may be a thin film of a precious metal. In accordance with the various implementations of the invention, the precious metal may include, but is not limited to, noble metals such as palladium, platinum, gold, silver, iridium, and rhodium, as well as other metals such as copper.

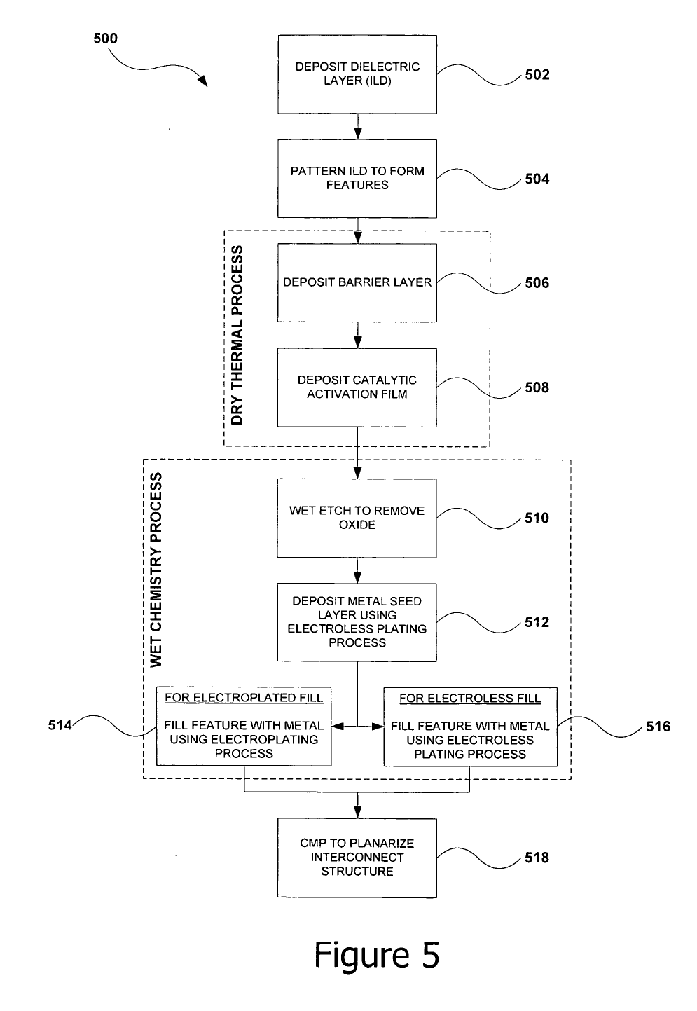

FIG. 5 is a method 500 for forming an interconnect using a catalytic activation film in accordance with an implementation of the invention. First a dielectric layer is deposited upon a substrate, such as a semiconductor wafer or an interconnect layer of a semiconductor device (502). The dielectric layer is generally used as an interlayer dielectric (ILD). Example of dielectric materials that may be used to form the dielectric layer include, but are not limited to, silicon dioxide (SiO₂), carbon doped oxide (CDO), organic polymers such as perfluorocyclobutane (PFCB), and fluorosilicate glass (FSG).

The dielectric layer is patterned using conventional photolithography processes to form features, such as vias and trenches, in which interconnects may be formed (504). The photolithography process may include many steps such as depositing a photoresist layer atop the dielectric layer, patterning the photoresist layer using ultraviolet radiation exposed through a mask, developing the photoresist layer, etching the dielectric layer, and removing the photoresist layer. A cleaning operation may also be performed on the etched features.

After the dielectric layer has been etched to form features, a dry thermal portion of the method 500 is carried out. First, a dry thermal process is used to deposit a barrier layer atop the dielectric layer (506). The barrier layer protects the underlying dielectric layer from metal that would otherwise diffuse out of the interconnect structure and penetrate into the dielectric layer. The diffusion of metal would lead to electrical shorts and would decrease the reliability of the interconnect. Dry thermal processes that may be used to deposit the barrier layer include, but are not limited to, PVD, CVD, ALD, iALD, or ICB. The dry thermal process is performed under vacuum conditions within a reaction chamber. Materials that may be deposited to form the barrier layer include, but are not limited to, one or combinations of titanium (Ti), tantalum (Ta), titanium nitride (TiN), titanium carbide (TiC), titanium silicon carbide (TiSiC), titanium carbonitride (TiCN), tantalum nitride (TaN), tantalum carbide (TaC), tantalum carbonitride (TaCN), tungsten carbide (WC), tungsten nitride (WN), and tungsten carbonitride (WCN).

Within the same reaction chamber and without breaking vacuum, another dry thermal process is used to deposit a thin catalytic activation film atop the barrier layer (508). Dry thermal processes that may be used to deposit the thin catalytic activation film include, but are not limited to, PVD, CVD, ALD, iALD, or ICB. The catalytic activation film may be a thin film of a precious metal such as palladium, platinum, gold, silver, iridium, or rhodium. The catalytic activation film is therefore deposited directly on the barrier layer prior to oxide formation. In alternate implementations of the invention, a different reaction chamber may be used or the vacuum may be broken between the barrier layer deposition and the catalytic activation film deposition.

Next, a wet chemistry portion of the method 500 is carried out. First, an optional wet etch process may be used to remove any oxide that may have formed on the catalytic activation film and/or on any exposed portions of the underlying barrier layer (510). The oxide may form when the substrate is removed from the reaction chamber where the dry thermal processes were carried out. Removal of any native oxide enhances adhesion between the catalytic activation layer and any subsequently deposited layers. This also enhances adhesion between the exposed portions of the underlying barrier layer and any subsequently deposited layers.

A wet chemistry plating process is then carried out to deposit a metal layer. For instance, in one implementation, an electroless plating process may be carried out to deposit a continuous metal layer atop the catalytic activation film and the barrier layer (512). As described above, the catalytic activation film enables the chemistry necessary for the electroless plating process to occur. The metal deposited by the electroless plating process may be copper metal. In alternate implementations, a variety of metals other than copper may be used, including but not limited to copper alloys, cobalt, cobalt boron, cobalt phosphorus, cobalt boron phosphorus, cobalt tungsten boron, other cobalt alloys, nickel, nickel phosphorus, nickel boron, other nickel alloys, ruthenium, and ruthenium alloys.

In some implementations of the invention, the metal layer deposited by the electroless plating process may be a metal seed layer, such as a copper seed layer. In that case, the metal seed layer may be used to catalyze another wet chemistry plating process, such as an electroplating process, to fill the feature with metal (514). In other implementations, the electroless plating process continues until the feature is filled with metal (516).

After the feature has been filled with metal, a chemical mechanical polishing (CMP) process is carried out to planarize the deposited metal layer and complete the formation of the interconnect (518). The CMP process removes excess material, such as excess metal, excess precious metal, and excess barrier layer metal. The CMP process also planarizes a top surface of the structure to form the completed interconnect. The entire process may then be repeated to form multi-layered structures.

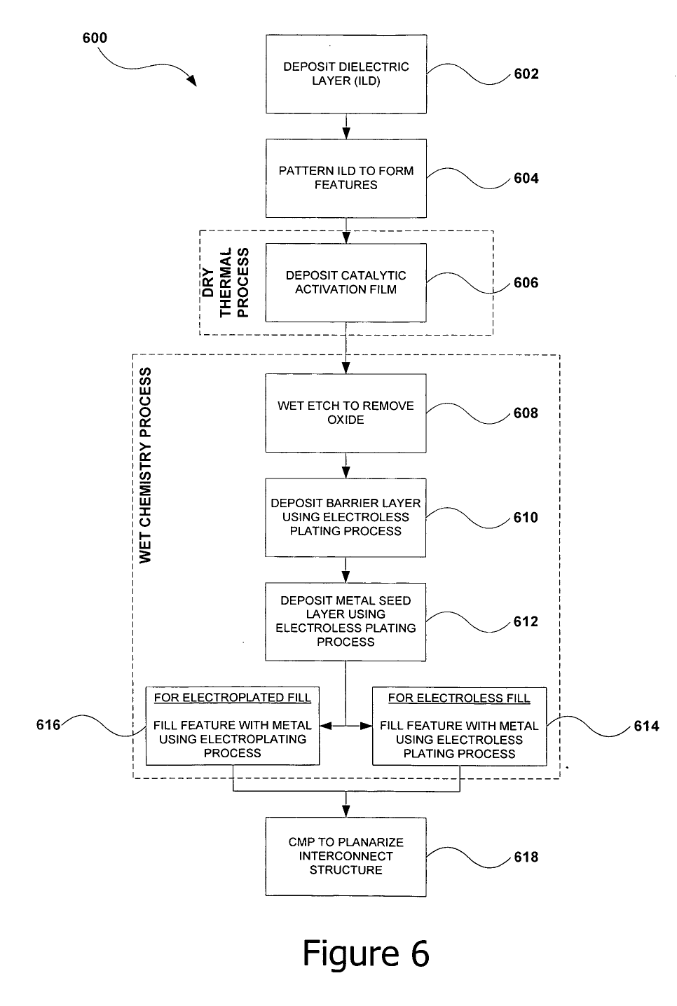

FIG. 6 is a method 600 for forming a barrier layer using a catalytic activation film in accordance with an implementation of the invention. First, a dielectric layer is deposited upon a substrate, such as a semiconductor wafer or an interconnect layer of a semiconductor device (602). The dielectric layer is generally used as an ILD and may be formed using materials that include, but are not limited to, SiO₂, CDO, PFCB, and FSG. Features such as vias and trenches are patterned into the dielectric layer using conventional photolithography processes (604). A cleaning operation may also be performed on the etched features.

After the dielectric layer has been etched to form features, a dry thermal process is used to deposit a thin catalytic activation film directly atop the dielectric layer (606). Dry thermal processes that may be used to deposit the thin catalytic activation film include, but are not limited to, PVD, CVD, ALD, iALD, or ICB. The catalytic activation film may be a thin film of a precious metal such as palladium, platinum, gold, silver, iridium, or rhodium. The dry thermal process is performed under vacuum conditions within a reaction chamber.

The wet chemistry portion of the method 600 is carried out next. First, an optional wet etch process may be used to remove any oxide that may have formed on the catalytic activation film (608). Again, the oxide may form when the substrate is removed from the reaction chamber where the dry thermal process was carried out. Removal of any native oxide enhances adhesion between the catalytic activation layer and any subsequently deposited layers.

An electroless plating process is then carried out to deposit a continuous barrier layer atop the catalytic activation film (610). As described above, the catalytic activation film enables the chemistry necessary for the electroless plating process to occur. Metals that may be deposited by the electroless plating process to form the barrier layer include, but are not limited to, one or combinations of cobalt, cobalt alloys, nickel, nickel alloys, ruthenium, and ruthenium alloys.

Once the barrier layer is formed, metallization may be carried out using either an electroplating process, an electroless plating process, or a combination of both. For example, in some implementations of the invention, another electroless plating process may be carried out to deposit a continuous metal layer atop the barrier layer (612). The electroless plating process may then continue until the feature is filled with metal (614). Alternatively, the continuous metal layer may act as a metal seed layer and an electroplating process may follow to fill the feature with a metal (616). In further implementations of the invention, an electroplating process may directly follow deposition of the barrier layer to fill the feature with metal. In yet further implementations, an electroplating process or a dry thermal process may be used to form the metal seed layer atop the electrolessly deposited barrier layer. The metal deposited by the electroless plating process and/or the electroplating process may be any of a variety of metals, including but not limited to copper metal or copper alloys. After the feature has been filled with metal, a CMP process is carried out to complete formation of the interconnect (618). The entire process may then be repeated to form multi-layered structures.

In some implementations of the invention, the methods of FIGS. 5 and 6 may both be used in a single structure. As such, two catalytic activation films may be employed, a first film to electrolessly deposit a barrier layer onto a dielectric substrate, and a second film to electrolessly deposit a subsequent layer of metal onto the barrier layer.

Implementations of the invention offer many advantages over conventional processes for forming seed layers and filling features such as narrow trenches. As described above, implementations of the invention reduce or eliminate overhang of the seed layer at the opening of a feature, such as a narrow trench, due to the thinness of the catalytic activation film. The substantial reduction or elimination of overhang reduces the formation of voids within the feature and prevents a breakdown in the metallization of the feature if an electroplating process is used. The catalytic activation film also deals with the issue of non-uniform side wall coverage that occurs when metal seed layers are deposited using conventional methods such as PVD. As described above, implementations of the invention utilize an electroless deposition process to deposit the metal seed layers that results in substantially improved sidewall coverage. The improvement in side wall coverage and uniformity directly increases the reliability of the feature.

Furthermore, the use of a dry thermal process to deposit the palladium prevents palladium colloids from being carried over into the electroless plating bath. In conventional processes, because a wet chemistry technique is used to deposit the palladium onto a substrate, palladium colloids may be inadvertently carried over into a subsequent electroless deposition process, thereby contaminating the electroless plating bath and causing bath plate out. In accordance with implementations of the invention, however, since a dry thermal process is used to deposit the Pd, there are no Pd colloids to be carried over.

Accordingly, a method for depositing a catalytic activation film to enable the electroless deposition of a metal layer on a non-catalytic substrate has been disclosed. As described above, the catalytic activation film may include one or more discontinuities that will not adversely affect a metal layer that is subsequently deposited using an electroless plating process. The subsequently deposited metal layer will tend to be a continuous layer with substantially no discontinuities.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a substrate having a dielectric layer, wherein a feature is formed in the dielectric layer;
depositing a barrier layer on the dielectric layer and within the feature;
depositing a catalytic activation film on the barrier layer;
depositing at least one metal layer on the catalytic activation film to fill the feature; and
planarizing the deposited metal layer to form an interconnect.

2. The method of claim 1, wherein the depositing of the at least one metal layer on the catalytic activation film comprises:
employing an electroless plating process to deposit a metal layer onto the catalytic activation film, wherein the feature is filled by the metal layer.

3. The method of claim 1, wherein the depositing of the at least one metal layer on the catalytic activation film comprises:
employing an electroless plating process to deposit a metal seed layer onto the catalytic activation film; and
employing an electroplating process to deposit a metal layer onto the metal seed layer, wherein the feature is filled by the metal layer.

4. The method of claim 1, wherein the depositing of the barrier layer comprises employing a first dry thermal process to deposit the barrier layer.

5. The method of claim 4, wherein the first dry thermal process comprises PVD, CVD, ALD, iALD, or ICB.

6. The method of claim 4, wherein the first dry thermal process is employed within a reaction chamber under vacuum conditions.

7. The method of claim 5, wherein the barrier layer comprises at least one of Ti, Ta, TiN, TiC, TiSiC, TiCN, TaN, TaC, TaCN, WC, WN, or WCN.

8. The method of claim 1, wherein the depositing of the catalytic activation film comprises employing a second dry thermal process to deposit the catalytic activation film layer.

9. The method of claim 8, wherein the second dry thermal process comprises PVD, CVD, ALD, iALD, or ICB.

10. The method of claim 8, wherein the second dry thermal process is employed within a reaction chamber under vacuum conditions.

11. The method of claim 1, wherein the catalytic activation film comprises a thin film of a precious metal.

12. The method of claim 11, wherein the precious metal comprises at least one of palladium, platinum, gold, silver, iridium, or rhodium.

13. The method of claim 1, wherein the catalytic activation film includes one or more discontinuities.

14. The method of claim 2, wherein the metal layer comprises a copper layer.

15. The method of claim 3, wherein the metal layer comprises a copper layer.

16. The method of claim 3, wherein the metal seed layer comprises a copper seed layer.

17. The method of claim 1, further comprising performing a wet etch process to remove oxide that may have formed on the catalytic activation film or on the barrier layer.

18. The method of claim 1, wherein the dielectric layer comprises SiO₂ or CDO.

19. The method of claim 1, wherein the feature comprises a trench or a via.

20. A method comprising:
providing a substrate having a dielectric layer, wherein a feature is formed in the dielectric layer;
depositing a catalytic activation film on the dielectric layer and within the feature;
depositing a barrier layer on the catalytic activation film;
depositing at least one metal layer on the barrier layer to fill the feature; and
planarizing the deposited metal layer to form an interconnect.

21. The method of claim 20, wherein the depositing of the at least one metal layer on the barrier layer comprises:
employing an electroless plating process to deposit a metal layer onto the barrier layer, wherein the feature is filled by the metal layer.

22. The method of claim 20, wherein the depositing of the at least one metal layer on the barrier layer comprises:
employing an electroless plating process to deposit a metal seed layer onto the barrier layer; and
employing an electroplating process to deposit a metal layer onto the metal seed layer, wherein the feature is filled by the metal layer.

23. The method of claim 20, wherein the depositing of the catalytic activation film comprises employing a dry thermal process to deposit the catalytic activation film layer.

24. The method of claim 23, wherein the dry thermal process comprises PVD, CVD, ALD, iALD, or ICB.

25. The method of claim 20, wherein the catalytic activation film comprises at least one of palladium, platinum, gold, silver, iridium, or rhodium.

26. The method of claim 20, wherein the catalytic activation film includes one or more discontinuities.

27. The method of claim 20, wherein the depositing of the barrier layer comprises employing an electroless plating process to deposit the barrier layer.

28. The method of claim 27, wherein the barrier layer comprises at least one of cobalt, a cobalt alloy, nickel, a nickel alloy, ruthenium, or a ruthenium alloy.

29. The method of claim 21, wherein the metal layer comprises a copper layer.

30. The method of claim 22, wherein the metal layer comprises a copper layer.

31. The method of claim 22, wherein the metal seed layer comprises a copper seed layer.

32. The method of claim 20, further comprising performing a wet etch process to remove oxide that may have formed on the catalytic activation film.

33. A method comprising:
providing a silicon wafer having a dielectric layer, wherein a trench is formed in the dielectric layer;
employing a first dry thermal process to deposit a barrier layer on the dielectric layer and within the trench;
employing a second dry thermal process to deposit a catalytic activation film on the barrier layer;
employing a wet chemistry plating process to deposit at least one metal layer on the catalytic activation film to fill the trench; and
planarizing the deposited metal layer to form an interconnect.

34. The method of claim 33, wherein the first dry thermal process and the second dry thermal process are performed in sequence within a reaction chamber under vacuum conditions, wherein the vacuum is not broken between the first dry thermal process and the second dry thermal process.

35. The method of claim 33, wherein the employing of a wet chemistry plating process comprises:
employing an electroless plating process to deposit a metal layer onto the catalytic activation film, wherein the trench is filled by the metal layer.

36. The method of claim 33, wherein the employing of a wet chemistry plating process comprises:
employing an electroless plating process to deposit a metal seed layer onto the catalytic activation film; and
employing an electroplating process to deposit a metal layer onto the metal seed layer, wherein the trench is filled by the metal layer.

37. A method comprising:
providing a silicon wafer having a dielectric layer, wherein a trench is formed in the dielectric layer;
employing a dry thermal process to deposit a catalytic activation film on the dielectric layer and within the trench;
employing a first wet chemistry plating process to deposit a barrier layer on the catalytic activation film;
employing a second wet chemistry plating process to deposit at least one metal layer on the barrier layer to fill the trench; and
planarizing the deposited metal layer to form an interconnect.

38. The method of claim 37, wherein the employing of a first wet chemistry plating process comprises employing an electroless plating process to deposit a barrier layer on the catalytic activation film.

39. The method of claim 37, wherein the employing of a second wet chemistry plating process comprises:
employing an electroless plating process to deposit a metal layer onto the barrier layer, wherein the trench is filled by the metal layer.

40. The method of claim 37, wherein the employing of a second wet chemistry plating process comprises:
employing an electroless plating process to deposit a metal seed layer onto the barrier layer; and
employing an electroplating process to deposit a metal layer onto the metal seed layer, wherein the trench is filled by the metal layer.
